(19) United States
(12) Patent Application Publication
(10) Pub. No.: US 2019/0088557 A1
(43) Pub. Date: Mar. 21, 2019

(54) INTEGRATED CIRCUIT STRUCTURE INCLUDING DEEP N-WELL SELF-ALIGNED WITH STI AND METHOD OF FORMING SAME

(71) Applicant: GLOBALFOUNDRIES INC., Grand Cayman (KY)

(72) Inventors: Jagar Singh, Clifton Park, NY (US); Jerome J. B. Ciavatti, Mechanicville, NY (US)

(21) Appl. No.: 15/705,429

(22) Filed: Sep. 15, 2017

(51) Int. Cl. H01L 21/8238; H01L 27/092; H01L 29/06; H01L 29/08

(52) U.S. Cl. CPC H01L 21/823892; H01L 27/0928; H01L 29/0653; H01L 21/823814; H01L 21/823821; H01L 21/823878; H01L 29/0847

(57) ABSTRACT

The disclosure is directed to integrated circuit (IC) structures, and more particularly, to IC structures including a deep n-well that is self-aligned with a shallow trench isolation (STI). The integrated circuit structure may include: a first pair of isolation regions within a substrate; a first region of the substrate between the first pair of isolation regions having a first conductivity type; a second region of the substrate beneath the first pair of isolation regions and the first region of the substrate having a second conductivity type opposite the first conductivity type of the first region of the substrate, wherein the second region of the substrate includes a second pair of isolation regions that are self-aligned with and in contact with the first pair of isolation regions.

### BACKGROUND

### Technical Field

The present disclosure relates to integrated circuit (IC) structures, and more particularly, to IC structures including a deep n-well that is self-aligned with a shallow trench isolation (STI).

### Related Art

in complementary metal oxide semiconductor CMOS technologies, various isolation techniques are used to isolate adjacent devices within an individual integrated circuit (IC) structure. One common isolation technique is a shallow trench isolation (STI). STIs may be formed by etching a trench within a semiconductor material, e.g., a substrate, and filling the trench with an isolation medal, e.g., silicon oxide or silicon nitride. While STIs provide excellent isolation between adjacent devices or circuits, STIs are unable to provide isolation from signal coupling from one node to another within the substrate, or substrate noise. Recently, deep n-wells within the substrate are being introduced as alternative isolation platforms. Deep n-wells refer to ells which are formed at a greater depth, e.g., about 2.5 microns, within the substrate relative to standard n-well structures which are up to about 1.5 microns. However, deep n-well isolation platforms suffer from complex design rules which make them a non-competitive option and limit their application to analog and radio frequency (RF) circuits. Thus far, deep n-well isolation platforms have not been compatible with memory devices.

### SUMMARY

A first aspect of the disclosure is directed to an integrated circuit structure. The integrated circuit structure may include: a first pair of isolation regions within a substrate; a first region of the substrate between the first pair of isolation regions having a first conductivity type; a second region of the substrate beneath the first pair of isolation regions and the first region of the substrate having a second conductivity type opposite the first conductivity type of the first region of the substrate, wherein the second region of the substrate includes a second pair of isolation regions that are self-aligned with and in contact with the first pair of isolation regions.

A second aspect of the disclosure is directed to a method of forming an integrated circuit structure. The method may include: doping a first region of a substrate between a first pair of isolation regions with a first dopant having a first conductivity type; and doping a second region of the substrate beneath the first region of the substrate and the first pair of isolation regions with a second dopant having a second, opposite conductivity type, wherein the doping of the second region of the substrate includes doping the second region such that the doped second region of the substrate contacts a bottom surface of the first pair of isolation regions.

A third aspect of the disclosure is directed to an integrated circuit structure. The integrated circuit structure may include: a first pair of isolation regions within a substrate; a first region of the substrate between the first pair of isolation regions including a p-well; a second region of the substrate beneath the first pair of isolation regions and the first region of the substrate, the second region of the substrate including a deep n-well, wherein the deep n-well includes a second pair of isolation regions that are self-aligned with and in contact with a bottom surface of the first pair of isolation regions; a set of fins over the substrate; a gate structure over the substrate and the set of fins such that the gate structure extends perpendicularly relative to the set of fins; and source/drain regions on opposing sides of the gate structure over the set of fins.

The foregoing and other features of the disclosure will be apparent from the following more particular description of embodiments of the disclosure.

### BRIEF DESCRIPTION OF THE DRAWINGS

The embodiments of this disclosure will be described in detail, with reference to the following figures, wherein like designations denote like elements, and wherein:

FIGS. 1-3 show cross-sectional views of an integrated circuit structure undergoing aspects of a method according to embodiments of the disclosure.

FIGS. 4-6 show a resulting integrated circuit structure according to embodiments of the disclosure, wherein FIG. 4 shows a top-down view of the integrated circuit structure and FIGS. 5-6 show cross-sectional views of the integrated circuit structure of FIG. 4.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

The present disclosure relates to integrated circuit (IC) structures, and more particularly, to IC structures including a deep n-well that is self-aligned with a shallow trench isolation (STI). Embodiments of the present disclosure provide for self-aligned deep n-well isolation platform that is compatible with any device, e.g., memory devices, analog circuits, and RF circuits, and eliminates substrate noise. Additionally, the self-aligned deep n-well isolation platform of the present disclosure does not suffer from complex design rules. The deep n-well structure is aligned with a bottom surface of the STI such that the STI isolation is extended.

It will also be understood that when an element such as a layer, region, or substrate is referred to as being “on” or “over” another element, it may be directly on the other element or intervening elements may also be present. In contrast, when an element is referred to as being “directly on” or “directly over” another element, there may are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Methods as described herein may be used in the fabrication of IC chips. The resulting integrated circuit chips may be integrated with other chips, discrete circuit elements, and/or other signal processing devices as part of either (a) an intermediate product, such as a motherboard, or (b) an end product. The end product can be any product that includes integrated circuit chips.

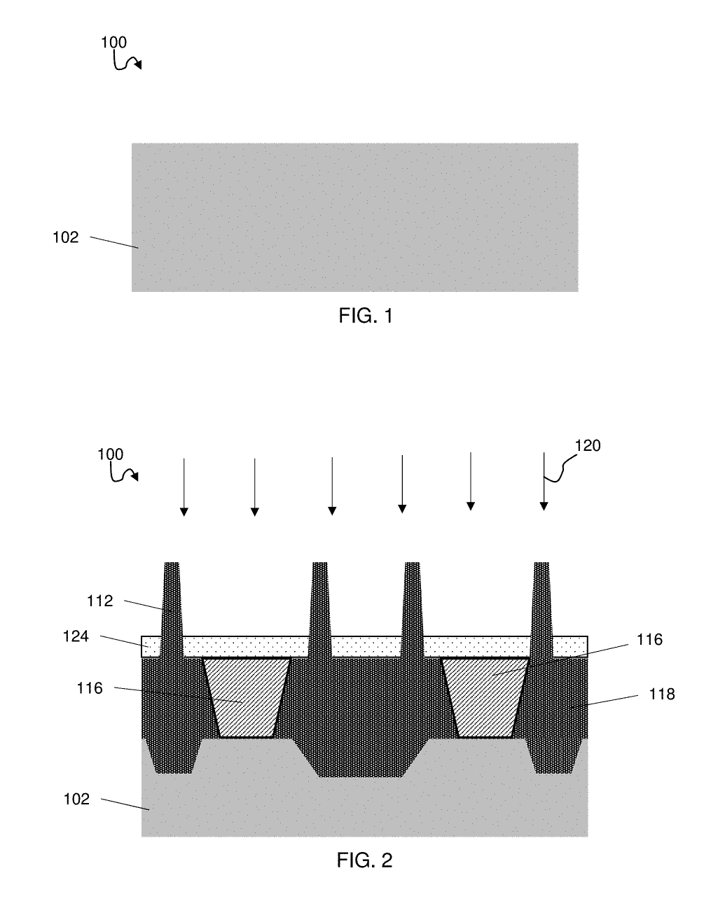

Referring to FIG. 1, a cross-sectional view of a precursor structure 100 to be processed according to embodiments of the disclosure is shown. Precursor structure 100 may represent a portion of a larger integrated circuit (IC) structure which has previously been formed, processed, etc., to include the various initial structures known in the art. Precursor structure 100 can be structured to include a substrate 102. As shown, substrate 102 may include any currently-known or later developed material capable of being processed into a transistor structure, and may include, e.g., a bulk semiconductor layer, a semiconductor-on-insulator (SOI) substrate, etc. Substrate 102 thus may overlie one or more other layers of material having distinct material and/or electrical properties, with such layers of material being omitted from the accompanying FIGS. to better illustrate structures and processes to form an IC structure according to the disclosure. Substrate 102 may include any currently known or later developed semiconductor material, which may include without limitation, silicon, germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, the entirety of substrate 102 or a portion thereof may be strained. Substrate 102 may include a p-type substrate. The resistivity of substrate 102 may be, for example, about 8-12 ohm-centimeters (ohm-cm).

Substrate 102 of precursor structure 100 may be formed by forming a semiconductor material on an underlying structure (not shown). According to an example, substrate 102 can be formed by deposition and/or wafer bonding, e.g., separation by implantation of oxygen (SIMOX). As used herein, the term “depositing” may include any now known or later developed technique appropriate for deposition, including but not limited to, for example: chemical vapor deposition (CVD), low-pressure CVD (LPCVD), plasma-enhanced CVD (PECVD), semi-atmosphere CVD (SACVD) high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

Referring now to FIG. 2, one or more (or a set of) fins 112 may be formed from substrate 102. Each fin 112 may be formed by forming a mask (not shown) over various portions of a semiconductor layer, and patterning and etching the mask such that a portion of the mask remains intact where fin(s) 112 are desired. Subsequently, the original semiconductor material may be etched such that the portion of substrate 102 that is covered or protected by the mask forms fin 112. Masks appropriate for the formation of fins 112 may include a single layer or combination of layers formed from, e.g., silicon nitride, or any other hard mask material known in the art. While four fins 112 are shown in precursor structure 100, it is understood that any number of fins 112 (e.g., one fin, five fins, one hundred fins, one thousand or more fins, etc.) may be formed on substrate 102 without departing from aspects of the disclosure. The embodiments described herein are thus operable for processing one fin 112 and/or multiple fins 112.

As used herein, “etching” generally refers to the removal of material from a substrate or structures formed on the substrate by wet or dry chemical means. In some instances, it may be desirable to selectively remove material from certain areas of the substrate. In such an instance, a mask may be used to prevent the removal of material from certain areas of the substrate. There are generally two categories of etching, (i) wet etch and (ii) dry etch. Wet etching may be used to selectively dissolve a given material and leave another material relatively intact. Wet etching is typically performed with a solvent, such as an acid. Dry etching may be performed using a plasma which may produce energetic free radicals, or species neutrally charged, that react or impinge at the surface of the wafer. Neutral particles may attack the wafer from all angles, and thus, this process is isotropic. Ion milling, or sputter etching, bombards the wafer with energetic ions of noble gases from a single direction, and thus, this process is highly anisotropic. A reactive-ion etch (RIE) operates under conditions intermediate between sputter etching and plasma etching and may be used to produce deep, narrow features, such as trenches.

Further, one or more (or as shown in FIG. 2, a pair of) isolation regions 116 may be formed within substrate 102 to isolate adjacent devices from one another. Isolations regions 116 may include shallow trench isolations (STIs) which may be formed by etching a trench within substrate 102 using a mask (not shown) and filling the trench, e.g., depositing, with an isolation material. The isolation material may include any now known or later developed isolation materials, for example, silicon oxide or silicon nitride.

Still referring to FIG. 2, a first region 118 of substrate 102 may be doped with a first dopant 120 having a first conductivity type. First region 118 of substrate 102 may include fins 112 and an area of substrate 102 surrounding pair of isolation regions 116 including between the pair. Dopant 120 may include, e.g., a p-type dopant. As known in the art, p-type dopants may include boron (B), indium (In) and gallium (Ga). P-type is element introduced to semiconductor to generate free hole (by “accepting” electron from semiconductor atom and “releasing” hole at the same time); acceptor atom must have one valence electron less than host semiconductor; boron (B) is the most common acceptor in silicon technology; alternatives include indium and gallium (gallium features high diffusivity in SiO₂, and hence, oxide cannot be used as mask during Ga diffusion). The doping may be accomplished by ion implantation, e.g., with a mask (not shown) or without in place. The energy level and the dosage of the dopants may be dependent on desired depth of implantation and application of the overall IC structure 100. As energy and dosage increases, the deeper the implantation within substrate 102 will take place. As the energy and dosage decreases, the less deep the implantation within substrate 102 will take place. In one example, the energy used may be approximately 20 keV to approximately 600 keV. As a result of the doping being performed after the formation of fins 112 and pair of isolation regions 116, dopant 120 may be implanted deeper where substrate 102 is absent of pair of isolation regions 116. That is, part of the implanting is being blocked by pair of isolation regions 116. Pair of isolation regions 116 has a shallow implant penetration compared to substrate 102. As a result, dopant 120 is not implanted as deep within substrate 102 beneath pair of isolation regions 116 that it is within substrate 102 without isolation regions 116. More specifically, during the doping of first region 118 of substrate 102, first dopant 130 is implanted to a depth within substrate 102 at a position directly beneath isolation regions 116 that is less than an implanted depth of first dopant 130 within substrate 102 between isolation regions 116. Pair of isolation regions 116 including silicon nitride may result in even greater implant blocking than isolations regions 116 including silicon oxide.

In addition, dielectric 124 may be optionally formed over substrate 102 between fins 112. Dielectric 124 may include, for example, silicon oxide (SiO2). Other dielectric materials can include, e.g., silicon nitride (Si3N4), fluorinated SiO2 (FSG), hydrogenated silicon oxycarbide (SiCOH), porous SiCOH, boro-phospho-silicate glass (BPSG), silsesquioxanes, near frictionless carbon (NFC), carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available from JSR Corporation, other low dielectric constant (<3.9) material, or layers thereof. Dielectric 124 may be formed before or after the doping of first region 118 of substrate 102. If formed before doping, dielectric 124 may impact the depth of the doping of dopants 120. For example, where dielectric 124 includes an oxide or a nitride, the dopants would be implanted not as deep as they would be without dielectric 124 because nitrides and oxides may be harder than substrate 102. A material that is said to be a “hard material” or “harder” may have a greater masking or dopant blocking capability than a material that is said to be a “softer material” or “softer”.

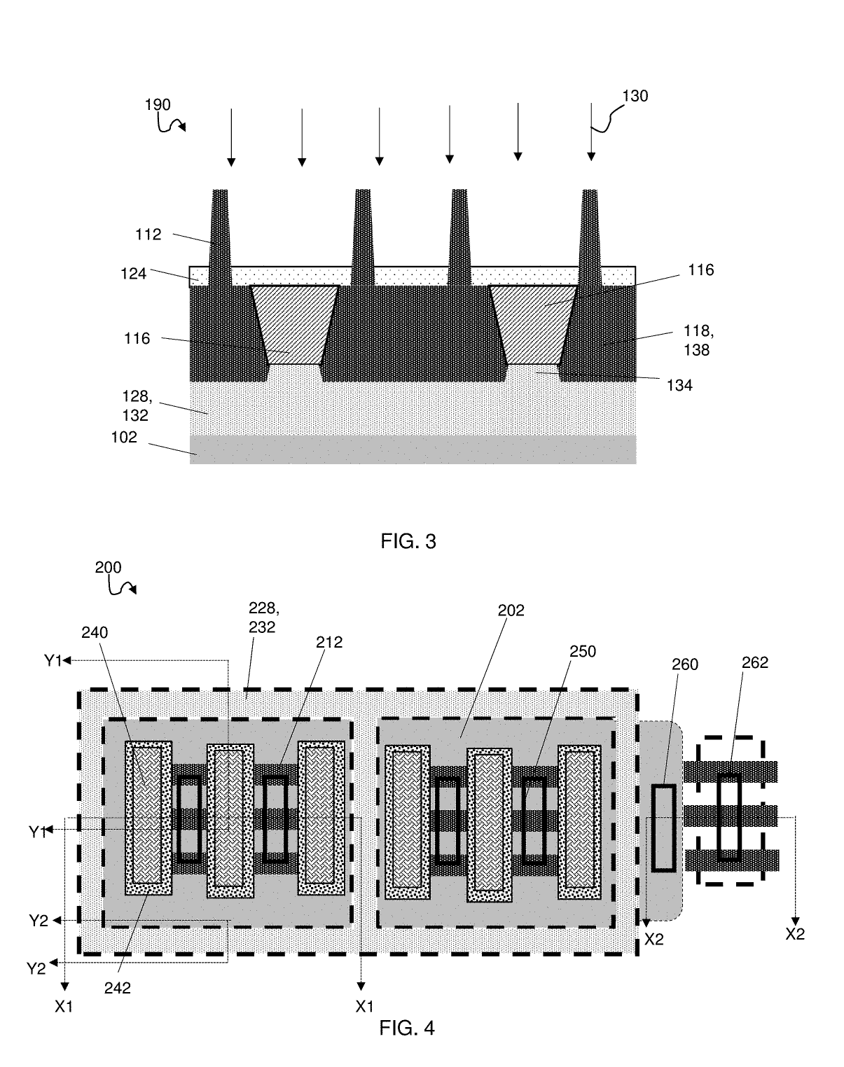

Turning now to FIG. 3, a second region 128 of substrate 102 beneath first region 118 of substrate 102 and pair of isolation regions 116 may be implanted with a second dopant 130 having a second, opposite conductivity type from first region 118. Dopant 130 may include, e.g., an n-type dopant. As known in the art, n-type dopants: may include but are not limited to: phosphorous (P), arsenic (As), antimony (Sb). N-type is element introduced to semiconductor to generate free electron (by “donating” electron to semiconductor); must have one more valance electron than semiconductor; common donors in silicon (Si): phosphorous (P), arsenic (As), antimony (Sb) and in gallium arsenic (GaAs): sulphur (S), selenium (Se), tin (Sn), silicon (Si), and carbon (C). As a result, second region 128 defines a deep n-well 132. The doping may be accomplished by ion implantation, e.g., with a mask (not shown) in place. For example, dopant 130 can be implanted at a high energy, e.g., about 120 to about 400 keV, or more particularly, about 180 keV. Further, dopant 130 may be implanted at a dose of about 1e12 to about 5e15. The doping of second region 128 of substrate 102 includes doping second region 128 such that the doped second region 128 contacts a bottom surface of pair of isolation regions 116. That is, deep n-well 132 is self-aligned with pair of isolation regions 116. This results in second isolation regions 134 being formed within second region 128 of substrate 102. Isolation regions 134 are self-aligned with and contact pair of isolation regions 116. Isolation regions 134 extend in a vertical direction within substrate 102 from deep n-well 132 to pair of isolation regions 116. Isolation regions 134 are composed of a portion of deep n-well 132 that is self-aligned with pair of isolation regions 116 and serve as an extension of the isolation of pair of isolation regions 116. Additionally, the formation of deep n-well 132 defines p-well regions 138 between pair of isolation regions 116 and above deep n-well 132.

The resulting IC structure 190 shown in FIG. 3 includes pair of isolation regions 116 within substrate 102 and fins 112 disposed over substrate 102. Substrate 102 may include a p-type substrate. First region 118 of substrate 102 may be disposed between pair of isolation regions 116 and have a first conductivity type. For example, the first conductivity type may be p-type. Second region 128 of substrate 102 may be disposed beneath pair of isolation regions 116 and first region 118 of substrate 102 and have a second conductivity type, opposite the first conductivity type of first region 118 of substrate 102. For example, the second conductivity type may be n-type. Second region 128 of substrate 102 may include isolation extensions 134 that are self-aligned with and in contact with pair of isolation regions 116. First region 118 of substrate 102 may include p-wells 138 and second region 128 of substrate 102 may include deep n-well 132. A dielectric 124 may be disposed over substrate 102 and between adjacent fins 112.

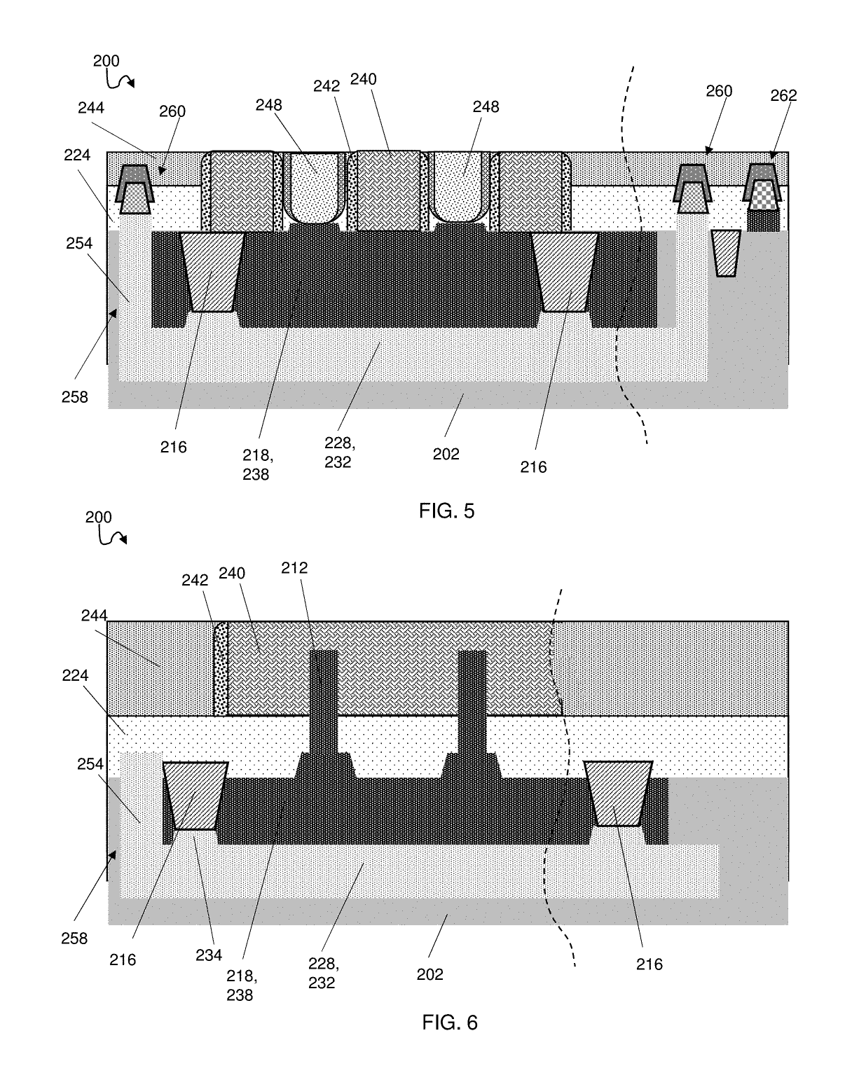

FIG. 4 shows an example of a top-down view of an IC structure 200 according to another embodiment of the disclosure after FinFET processing. FIGS. 5-6 show cross-sectional views of IC structure 200 of FIG. 4 wherein FIG. 5 is a cross-sectional view taken along line X1-X1 (along a fin) and X2-X2, and FIG. 6 is a cross-sectional view taken along line Y1-Y1 (taken along a gate structure) and Y2-Y2. More specifically, the left side of the dotted line of FIG. 5 corresponds to the cross-section of FIG. 4 taken along line X1-X1, while the right side of the dotted of FIG. 5 corresponds to a cross-section of FIG. 4 taken along line X2-X2. Further, the left side of the dotted line of FIG. 6 corresponds to the cross-section of FIG. 4 taken along line Y1-Y1, while the right side of the dotted of FIG. 6 corresponds to a cross-section of FIG. 4 taken along line Y2-Y2 It is to be understood that some features of IC structure 200 shown in FIGS. 5-6 are not shown in FIG. 4 in order to view gate structures and fins within IC structure 200 so that it is understood where the cross-sections of FIGS. 5 and 6 are taken.

Referring to FIGS. 5 and 6 together, IC structure 200 may include pair of isolation regions 216 within substrate 202 and fins 212 disposed over substrate 202. Substrate 202 may include a p-type substrate. First region 218 of substrate 202 may be disposed between pair of isolation regions 216 and have a first conductivity type. For example, the first conductivity type may be p-type. Second region 228 of substrate 202 may be disposed beneath pair of isolation regions 216 and first region 218 of substrate 202 and have a second conductivity type, opposite the first conductivity type of first region 218 of substrate 202. For example, the second conductivity type may be n-type. Second region 228 of substrate 202 may include isolation extensions 234 that are self-aligned with and in contact with pair of isolation regions 216. First region 218 of substrate 202 may include p-wells 238 and second region 228 of substrate 202 may include deep n-well 232. A dielectric 224 may be disposed over substrate 202 and between adjacent fins 212. The structures described thus far relative to FIGS. 4-6 may be fabricated as discussed relative to FIGS. 1-3.

After formation of self-aligned deep n-well 232, one or more gate structures 240 may be formed over substrate 202 and fins 212 within a dielectric layer 244 such that gate structure 240 extends perpendicular to fins 212. Gate structure 240 can be formed by conventional gate structure formation techniques, e.g., gate-first or gate-last processes, by deposition and etching of gate structure materials. Conventional gate structure materials may include: high-k dielectric followed by work function metal layers, optional barrier layers, and gate conductor layers, denoted together herein as “gate structure” and shown as a single layer in FIGS. 5-6 for brevity. As known in the art, high-k layers may include any dielectric material having a dielectric constant greater than 3.9, examples of which include: metal oxides tantalum oxide (Ta₂O₅), barium titanium oxide (BaTiO₃), hafnium oxide (HfO₂), zirconium oxide (ZrO₂), aluminum oxide (Al₂O₃) or metal silicates such as hafnium silicate oxide (Hf_{A1}Si_{A2}O_{A3}) or hafnium silicate oxynitride (Hf_{A1}Si_{A2}O_{A3}N_{A4}), where A1, A2, A3, and A4 represent relative proportions, each greater than or equal to zero and A1+A2+A3+A4 (1 being the total relative mole quantity). Work function metal layers may act as a doping source, and a different work function setting metal can then be employed depending on whether an n-type field-effect-transistor (NFET) or a p-type field-effect-transistor (PFET) device is desired. Thus, the same gate conductor can be used in each of the devices, yet a different (if so desired) work function setting metal can be used in one or more devices to obtain a different doping polarity. By way of example only, suitable work function setting metals for use in PFET devices include, but are not limited to aluminum, dysprosium, gadolinium, and ytterbium. Suitable work function setting metals for use in NFET devices include, but are not limited to lanthanum, titanium, and tantalum. Optional barrier layers may include, for example, titanium nitride, tantalum nitride, hafnium nitride, hafnium silicon nitride, titanium silicon nitride, tantalum silicon nitride, tungsten nitrogen carbide, and hafnium aluminum nitride. Gate conductor layers may include, for example, at least one of: titanium, titanium nitride, tungsten, tungsten nitride, copper, copper nitride, tantalum, or tantalum nitride. Further, spacers 242, e.g., including silicon nitride or silicon oxide, may be formed on opposing sides of gate structure 240 by depositing and etching as is known in the art.

Still referring to FIGS. 5-6, source/drain regions 248 may be formed on opposing sides of gate structure 240 over fins 212 within dielectric layer 244. Source/drains 248 can be formed on fin 112, e.g., by deposition, ion implantation, and/or selective epitaxial growth on fins 112. Source/drains 248 can include any semiconductor material appropriate for operation as a source/drain material in a transistor. Contacts 250 (FIG. 4) may be formed to connect source/drains 248 to other structures (not shown) elsewhere in IC structure 200.

As shown in FIG. 5, n-well fins 254 may be formed within a third region 258 of substrate 202 and may extend from a top surface of substrate 202 to second region 228 of substrate 202, or more particularly to deep n-well 232. Third region 258 of substrate 202 may be disposed outside of pair of isolation regions 116. N-well fins 254 may include a conductivity type that is the same as the conductivity type of second region 228, or deep n-well 232. N-well fins 254 may be formed by etching an opening within IC structure 200 (dielectric layers 224, 244 and substrate 202) and filling the opening with an n-type semiconductor material. Contacts 260 may be formed to n-well fins 254. Contacts 260 are formed over n-well fins 254, where n-well fins 254 are heavily doped with n+ implant to have ohmic contact over n-well fins 254. Metal silicides are formed over these highly doped (n+) to provide a metal contact to provide a resistance path to current flow or bias the well regions. Contacts 262 may also be formed through dielectric layers 224, 244 to substrate 202 as known in the art.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the terms “first,” “second,” and the like, do not denote any order, quantity, or importance, but rather are used to distinguish one element from another. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s). “Substantially” refers to largely, for the most part, entirely specified or any slight deviation which provides the same technical benefits of the disclosure.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An integrated circuit structure comprising:
a first pair of isolation regions within a substrate;
a first region of the substrate between the first pair of isolation regions having a first conductivity type;
a second region of the substrate beneath the first pair of isolation regions and the first region of the substrate having a second conductivity type opposite the first conductivity type of the first region of the substrate,
wherein the second region of the substrate includes a second pair of isolation regions that are self-aligned with and in contact with the first pair of isolation regions.

2. The integrated circuit structure of claim 1, wherein the first conductivity type is p-type and the second conductivity type is n-type.

3. The integrated circuit structure of claim 1, wherein the first region of the substrate includes a p-well and the second region of the substrate includes a deep n-well.

4. The integrated circuit structure of claim 1, further comprising:
a set of fins over the substrate;
a gate structure over the substrate and the set of fins extending perpendicular to the set of fins; and
source/drain regions on opposing sides of the gate structure over the set of fins.

5. The integrated circuit structure of claim 1, further comprising:
a third region of the substrate outside the first pair of isolation regions, the third region of the substrate including a fin therein extending from a top surface of the substrate to the second region of the substrate.

6. The integrated circuit structure of claim 5, wherein the fin includes a conductivity type that is the same as the second conductivity type.

7. The integrated circuit structure of claim 1, wherein the substrate is a p-type substrate.

8. A method of forming an integrated circuit structure, the method comprising:
doping a first region of a substrate between a first pair of isolation regions with a first dopant having a first conductivity type; and
doping a second region of the substrate beneath the first region of the substrate and the first pair of isolation regions with a second dopant having a second, opposite conductivity type, wherein the doping of the second region of the substrate includes doping the second region such that the doped second region of the substrate contacts a bottom surface of the first pair of isolation regions.

9. The method of claim 8, wherein the doping of the second region of the substrate includes doping the second region of the substrate such that a second pair of isolation regions are formed within the second region of the substrate, the second pair of isolation regions being self-aligned with and contact the first pair of isolation regions.

10. The method of claim 8, wherein the first conductivity type is p-type and the second conductivity type is n-type.

11. The method of claim 8, wherein the doping of the second region of the substrate includes forming a deep n-well and defining a p-well between the first pair of isolation regions.

12. The method of claim 8, further comprising:
prior to the doping of the first region of the substrate:
forming a set of fins over the substrate; and
forming the first pair of isolation regions within the substrate.

13. The method of claim 12, further comprising:
forming a gate structure over the substrate and the set of fins such that the gate structure extends perpendicular to the set of fins; and
forming source/drain regions on opposing sides of the gate structure over the set of fins.

14. The method of claim 8, wherein during the doping of the first region of the substrate, the first dopant is implanted to a depth within the substrate at a position directly beneath the first pair of isolation regions that is less than an implanted depth within the substrate of the first dopant between the first pair of isolation regions.

15. The method of claim 8, further comprising:
forming a fin within a third region of the substrate extending from a top surface of the substrate to the second region of the substrate, the third region of the substrate being disposed outside of the first pair of isolation regions, and wherein the fin includes a conductivity type that is the same as the second conductivity type.

16. An integrated circuit structure comprising:
a first pair of isolation regions within a substrate;
a first region of the substrate between the first pair of isolation regions including a p-well;
a second region of the substrate beneath the first pair of isolation regions and the first region of the substrate, the second region of the substrate including a deep n-well,
wherein the deep n-well includes a second pair of isolation regions that are self-aligned with and in contact with a bottom surface of the first pair of isolation regions;
a set of fins over the substrate;
a gate structure over the substrate and the set of fins such that the gate structure extends perpendicularly relative to the set of fins; and
source/drain regions on opposing sides of the gate structure over the set of fins.

17. The integrated circuit structure of claim 16, wherein the substrate is a p-type substrate.

18. The integrated circuit structure of claim 16, further comprising:
a third region of the substrate outside the first pair of isolation regions, the third region of the substrate including a fin extending from a top surface of the substrate to the second region of the substrate.

19. The integrated circuit structure of claim 18, wherein the fin is n-type doped.

20. The integrated circuit structure of claim 16, further comprising a dielectric layer over the substrate and the set of fins, the gate structure and the source/drain regions being disposed within the dielectric layer.
